(19) United States
(12) Patent Application Publication
(10) Pub. No.: US 2026/0312271 A1
(43) Pub. Date: Oct. 8, 2026

(54) IMPEDANCE TRANSFORMING TAPERED COUPLERS

(71) Applicant: Qorvo US, Inc., Greensboro, NC (US)

(72) Inventors: Kelly M. Lear, Longwood, FL (US); Mark Greene, Wylie, TX (US); Deepukumar M. Nair, Lake Mary, FL (US)

(21) Appl. No.: 19/552,252

(22) Filed: Feb. 27, 2026

Related U.S. Application Data
(60) Provisional application No. 63/782,170, filed on Apr. 2, 2025.

(51) Int. Cl. H01P 5/18; H01P 5/22; H01P 9/00; H01P 9/02; H03H 2/00

(52) U.S. Cl. CPC H01P 5/184; H01P 5/227; H01P 9/006; H01P 9/02; H03H 2/006

(57) ABSTRACT

An impedance-transforming tapered coupler is disclosed. In one aspect, a quadrature coupler may be formed based on coupled lines where the lines are tapered so as to have an impedance transformation from one end of the line to the other end of the line. This transformation may be used to transform the impedance at two port while having minimal impact on the overall bandwidth of the coupler. By including the impedance transformation in the coupled lines, there is reduced need for impedance matching elements in a separate circuit. Reduction or elimination of such separate impedance-matching elements may save space and also reduce insertion losses, resulting in higher efficiency.

### RELATED APPLICATION

The present application is related to U.S. Provisional Patent Application Serial No. 63/782,170 filed on Apr. 2, 2025, and entitled “IMPEDANCE TRANSFORMING TAPERED COUPLERS,” the disclosure of which is incorporated herein by reference in its entirety.

### BACKGROUND

### I. Field of the Disclosure

The technology of the disclosure relates generally to couplers and, more particularly, to quadrature couplers.

### II. Background

Wireless devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to increase data transfer rates. In the wireless context, this has led to the use of higher frequencies as wireless standards evolve. This evolution has necessitated changes in the circuitry used to support wireless transceivers. These changes provide room for innovation.

### SUMMARY

Aspects disclosed in the detailed description include impedance transforming tapered couplers. In particular, a quadrature coupler may be formed based on coupled lines where the lines are tapered so as to have an impedance transformation from one end of the line to the other end of the line. This transformation may be used to transform the impedance at two ports while having minimal impact on the overall bandwidth of the coupler. By including the impedance transformation in the coupled lines, there is reduced need for impedance matching elements in a separate circuit. Reduction or elimination of such separate impedance matching elements may save space and also reduce insertion losses, resulting in higher efficiency.

In this regard, in one aspect, a coupler is disclosed. The coupler includes a first port, a second port, and a first transmission line extending between the first port and the second port, the first transmission line comprising a first lateral width proximate the first port and a second lateral width proximate the second port, wherein the first lateral width is different than the second lateral width. The coupler also includes a third port, a fourth port, and a second transmission line extending between the third port and the fourth port, the second transmission line comprising a third lateral width proximate the third port and a fourth lateral width proximate the fourth port, wherein the third lateral width is different than the fourth lateral width.

In another aspect, a communication device is disclosed. The communication device includes a transceiver comprising an amplifier chain comprising a single-ended input, a differential output, and a coupler coupled between the single-ended input and the differential output, the coupler comprising a first port, a second port, and a first transmission line extending between the first port and the second port, the first transmission line comprising a first lateral width proximate the first port and a second lateral width proximate the second port, wherein the first lateral width is different than the second lateral width. The transceiver includes a third port, a fourth port, and a second transmission line extending between the third port and the fourth port, the second transmission line comprising a third lateral width proximate the third port and a fourth lateral width proximate the fourth port, wherein the third lateral width is different than the fourth lateral width.

In another aspect, a method of forming a coupler to provide impedance transformation between a single-ended input and a differential output is disclosed. The method includes forming a first port and a second port with a first transmission line extending between the first port and the second port, the first transmission line comprising a first lateral width proximate the first port and a second lateral width proximate the second port, wherein the first lateral width is different than the second lateral width. The method also includes forming a third port and a fourth port with a second transmission line extending between the third port and the fourth port, the second transmission line comprising a third lateral width proximate the third port and a fourth lateral width proximate the fourth port, wherein the third lateral width is different than the fourth lateral width.

### BRIEF DESCRIPTION OF THE DRAWINGS

FIG. 1A is a block diagram of a conventional amplifier chain with quadrature couplers before and after amplifying elements;

FIG. 1B is a block diagram of a conventional Doherty amplifier chain with a coupler before the amplifying elements;

FIG. 1C is a stylized drawing of a conventional quadrature branch line coupler;

FIG. 1D is a stylized drawing of a conventional rat race coupler;

FIG. 1E is an exploded side perspective view of a conventional straight line quadrature coupler;

FIG. 1F is an exploded side perspective view of a conventional quadrature coupler where the conductors of the coupler are coiled as is common to save space;

FIG. 2A is a block diagram of an amplifier chain with impedance transforming quadrature couplers according to aspects of the present disclosure;

FIG. 2B is a block diagram of a Doherty amplifier chain with an impedance transforming coupler according to aspects of the present disclosure;

FIG. 3A is an exploded side perspective view of an impedance transforming straight line coupler according to aspects of the present disclosure;

FIG. 3B is an exploded side perspective view of an impedance transforming quadrature coupler coiled to save space according to aspects of the present disclosure;

FIG. 4 is a stylized drawing of an impedance transforming quadrature branch line coupler according to aspects of the present disclosure;

FIG. 5 is a top plan view of the impedance transforming quadrature branch line coupler of FIG. 4;

FIG. 6 is an exploded side perspective view of the straight line coupler of FIG. 3A with added defected ground planes;

FIG. 7 is a stylized drawing of an impedance transforming rat race coupler according to aspects of the present disclosure; and

FIG. 8 is a block diagram of a wireless communication device, which may include impedance transforming couplers according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a," “an,” and “the” are intended to include the plural forms as well unless the context clearly indicates otherwise. It will be further understood that the terms “comprises," “comprising," “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include impedance transforming tapered couplers. In particular, a quadrature coupler may be formed based on coupled lines where the lines are tapered so as to have an impedance transformation from one end of the line to the other end of the line. This transformation may be used to transform the impedance at two ports while having minimal impact on the overall bandwidth of the coupler. By including the impedance transformation in the coupled lines, there is reduced need for impedance matching elements in a separate circuit. Reduction or elimination of such separate impedance matching elements may save space and also reduce insertion losses, resulting in higher efficiency.

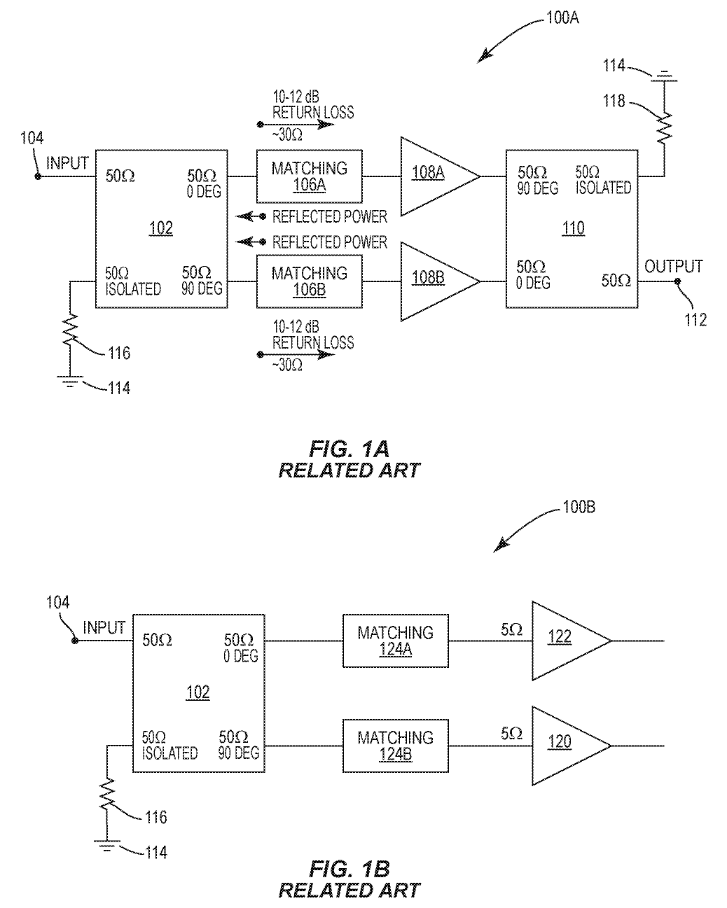

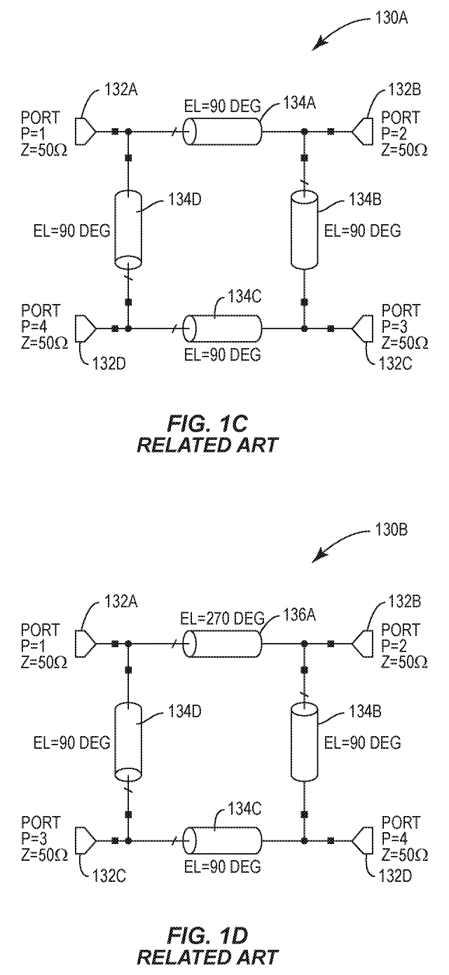

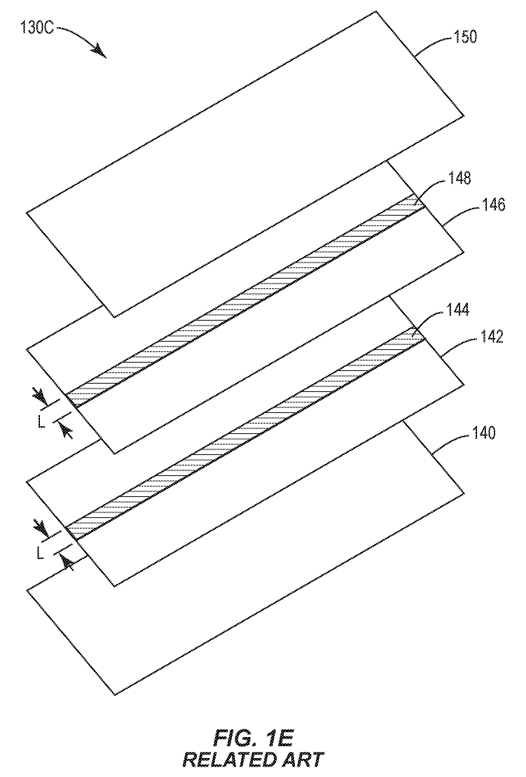

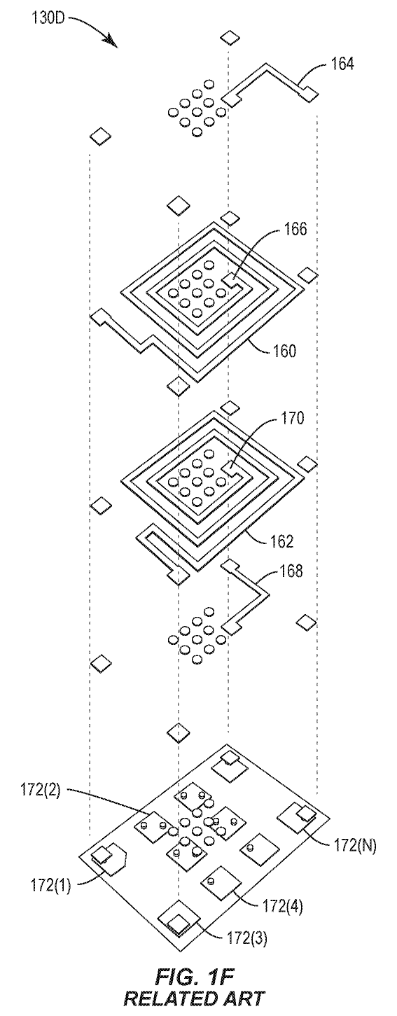

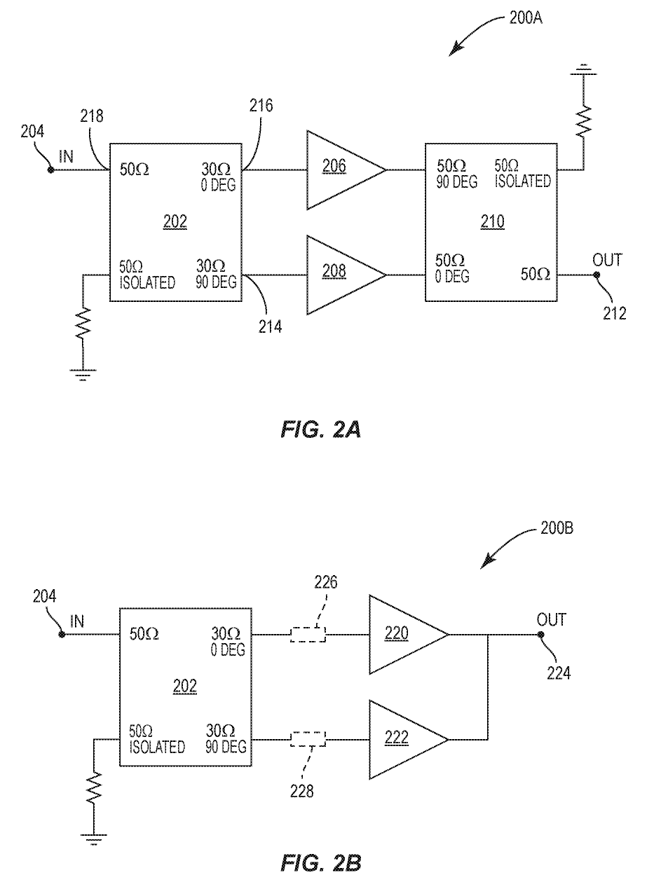

Before addressing aspects of the present disclosure, a brief overview of various conventional couplers and their potential shortcomings is provided with reference to FIGS. 1A-1F. A discussion of aspects of the present disclosure begins below with reference to FIG. 2A.

Couplers, and quadrature couplers in particular, are frequently used in amplifier chains to convert single ended signals to differential signals and vice versa. FIGS. 1A and 1B illustrate two such uses while FIGS. 1C-1F illustrate specific conventional couplers.

In this regard, FIG. 1A illustrates an amplifier chain 100A with a first input coupler 102 that converts a single ended signal at input 104 to a differential signal. The differential signal is provided to impedance matching circuits 106A, 106B before being amplified in amplifiers 108A, 108B. A second output coupler 110 converts the amplified differential signal to a single ended signal. The single ended signal is then output at output 112.

The first input coupler 102 is coupled to the input 104 at a first port, while a second port is coupled to ground 114 through a termination resistors 116. Similarly, the output coupler 110 has ports coupled to the amplifiers 108A, 108B and another port coupled to ground 114 through a second termination resistor 118.

In the first input coupler 102, the first port and the second port have a first impedance, typically around fifty ohms. Output ports likewise have the same first impedance. The inputs to the amplifiers 108A, 108B may have a lower impedance (e.g., thirty ohms). Accordingly, impedance matching circuits 106A, 106B are used to convert between the two impedances. The addition of impedance matching circuits 106A, 106B requires space for the components as well as adds insertion loss to the amplifier chain 100A. Still further, there may be other losses from reflections or the like.

FIG. 1B illustrates a similar Doherty amplifier chain 100B. The first input coupler 102 couples to a peaking amplifier 120 and a main amplifier 122. The amplifiers 120, 122 may have even lower impedances (e.g., five ohms) than the amplifiers 108A, 108B of FIG. 1A, so the impedance matching circuits 124A, 124B may be even more severe than the impedance matching circuits 106A, 106B of FIG. 1A. Likewise, the nature of the Doherty amplifier chain 100B allows elimination of the second coupler. However, the impedance matching circuits 124A, 124B still consume space and generate insertion loss.

There are several ways to make couplers, including a branch line coupler 130A as shown in FIG. 1C. The coupler has four ports 132A-132D, each having the same impedance (e.g., fifty ohms). The ports 132A-132D are coupled by four equal branch lines 134A-134D (e.g., transmission line) having an effective length of ninety degrees. That is, at the frequency of interest, the length is sufficient to impart a ninety-degree phase shift in signals. This arrangement allows the ports 132B, 132C to be ninety degrees different from one another (e.g., suitable for a differential signal).

While it has a similar structure, the rat race coupler 130B of FIG. 1D has one branch 136A which has an effective length of two hundred seventy degrees, causing the port 132C to be one hundred eighty degrees shifted relative to the port 132B.

More commonly, a coupler is formed from two parallel transmission lines. It may be conceptually appropriate to think of these two parallel lines being straight and sandwiched between ground planes, as illustrated by coupler 130C of FIG. 1E. That is, a first ground plane 140 may be positioned in a first plane. A first substrate 142 with a first transmission line 144 thereon is positioned above the ground plane 140. A second substrate 146 with a second transmission line 148 is positioned above the first substrate 142. A second ground plane 150 is positioned above the second transmission line 148. Conventionally, the transmission lines 144, 148 are parallel to one another and have a constant lateral dimension (L).

While the straight lines of the coupler 130C are easy to model and, if sufficiently long, may approach certain ideal conditions, such implementations are impractical in the space-constrained confines of modern electronic devices such as a mobile communication device. Accordingly, most conventional couplers are formed from parallel spiraling conductors, as better seen in FIG. 1F.

In this regard, FIG. 1F illustrates a coupler 130D where transmission lines 160, 162 are coiled and generally parallel to one another but in different planes. A “top” contact line 164 allows an electrical connection to an interior terminus 166 of the transmission line 160. Similarly, a “bottom” contact line 168 allows an electrical connection to an interior terminus 170 of the transmission line 162. Additional contacts 172(1)-172(N) may be provided to couple to ground or the like.

It should be appreciated that these couplers are provided by way of example and other coupler structures or geometries may exist and may benefit from aspects of the present disclosure.

FIGS. 2A & 2B illustrate exemplary uses for impedance transforming couplers where the couplers may be used to translate not only from differential signals to single-ended signals or vice versa in a power amplifier chain but also provide an impedance transformation (e.g., from a normal transmission line impedance of 50 ohms to match an amplifier input impedance of 30 ohms). In this regard, FIG. 2A illustrates an amplifier chain 200A having a first coupler 202 that converts a single-ended signal from an input 204 to a differential signal to be provided to amplifiers 206, 208. A second coupler 210 converts the differential signal from the amplifiers 206, 208 to a single ended signal at output 212. The first coupler 202 provides a phase shift at an output port 214 relative to the phase at an output port 216. Likewise, the input port 218 may have a first impedance (e.g., 50 ohms) and both output ports 214, 216 may have a lower impedance (e.g., 30 ohms) to match an input impedance of the amplifiers 206, 208. The second coupler 210 may not have the impedance shift because the outputs of the amplifiers 206, 208 may be, for example, 50 ohms and no transformation is needed.

A Doherty amplifier chain 200B may have the same single ended input 204 and first coupler 202 but uses main amplifier 220 and peaking amplifier 222 to provide a combined amplified output at output 224. Amplifiers 220, 222 may have even lower input impedances and accordingly, the first coupler 202 may not provide enough transformation. Thus, there may optionally be additional impedance matching circuits 226, 228. While this does not eliminate matching circuits, the overall size of the matching circuits may be reduced and may still provide a comparative advantage relative to a coupler that provides no impedance transformation.

It should be noted that there may be other amplifier chains that also benefit from an impedance matching coupler according to aspects of the present disclosure. Thus, while only two amplifier chains are shown, the present disclosure is not limited to just those two amplifier chains.

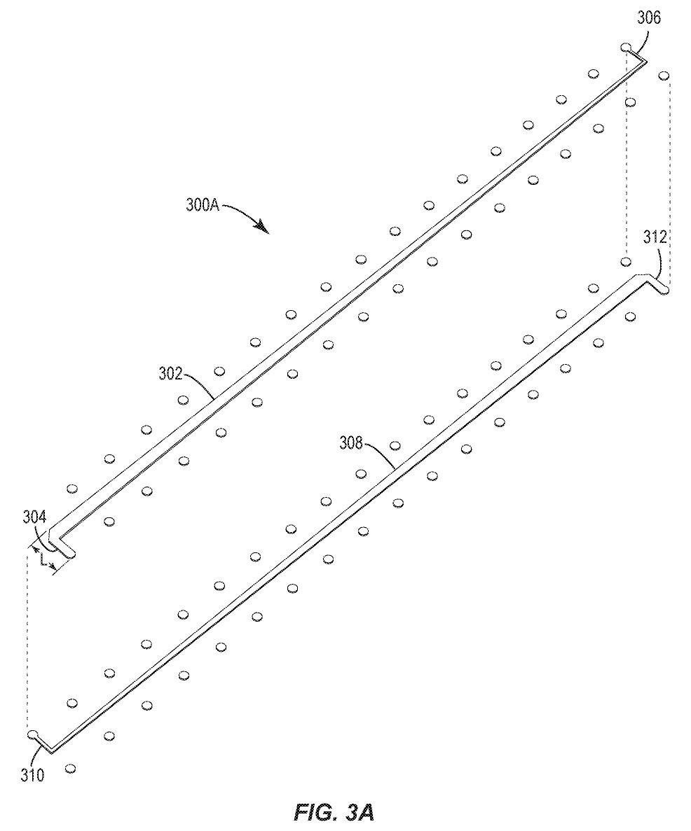

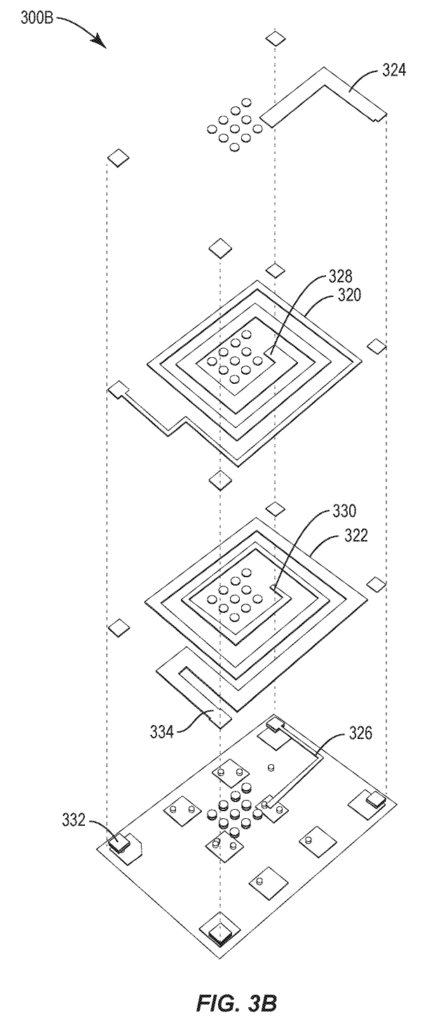

Exemplary aspects of the present disclosure provide impedance matching couplers by providing tapered transmission lines within the coupler. Taper, as used herein, means that there is a geometric change in the lateral dimension (L) of the transmission line from a relatively wide lateral dimension to a relatively narrow lateral dimension. It should be appreciated that such a taper changes the effective impedance of the transmission line. In general, the wider the transmission line, the lower the impedance, and the narrower the transmission line, the higher the impedance. There are limits on this generalization such as those imposed by skin effects and the like. Further, in many cases the impedance is frequency dependent, but as a general rule, the taper allows an impedance transformation from a high impedance to low impedance or vice versa. The transmission lines are, in the simplest example, tapered in opposite directions as better illustrated in FIGS. 3A & 3B . Still other tapers are possible and illustrated in other Figures.

In this regard, FIG. 3A illustrates an idealized parallel line coupler 300A. The coupler 300A has a first transmission line 302 with a first port 304 and a second port 306. The coupler 300A has a second transmission line 308 with a third port 310 and a fourth port 312. The first transmission line 302 tapers from first port 304 to the second port 306. Similarly, but in the opposite direction, the second transmission line 308 tapers from the fourth port 312 to the third port 310. When the transmission lines 302, 308 are stacked in assembled product, the thick part of the first transmission line 302 is over the thin part of the second transmission line 308 and the thin part of the first transmission line 302 is over the thick part of the second transmission line 308.

While the parallel line structure of the coupler 300A is relatively easy to model and shows proof of concept, it is not commercially viable. Accordingly, FIG. 3B is a more practical spiral structure for a coupler 300B. The coupler 300B has a first coiled or spiral transmission line 320 and a second coiled or spiral transmission line 322. The transmission lines 320, 322 are located in parallel planes (in the z-axis) and are generally positioned on top of one another. Contact lines 324, 326 connect to interior ends 328, 330 of the transmission lines 320, 322 similar to FIG. 1E. As with transmission lines 302, 308, the transmission lines 320, 322 are tapered. The first transmission line 320 is narrow at exterior end 332 and wide at interior end 328, while the second transmission line 322 is wide at exterior end 334 and narrow at interior end 330.

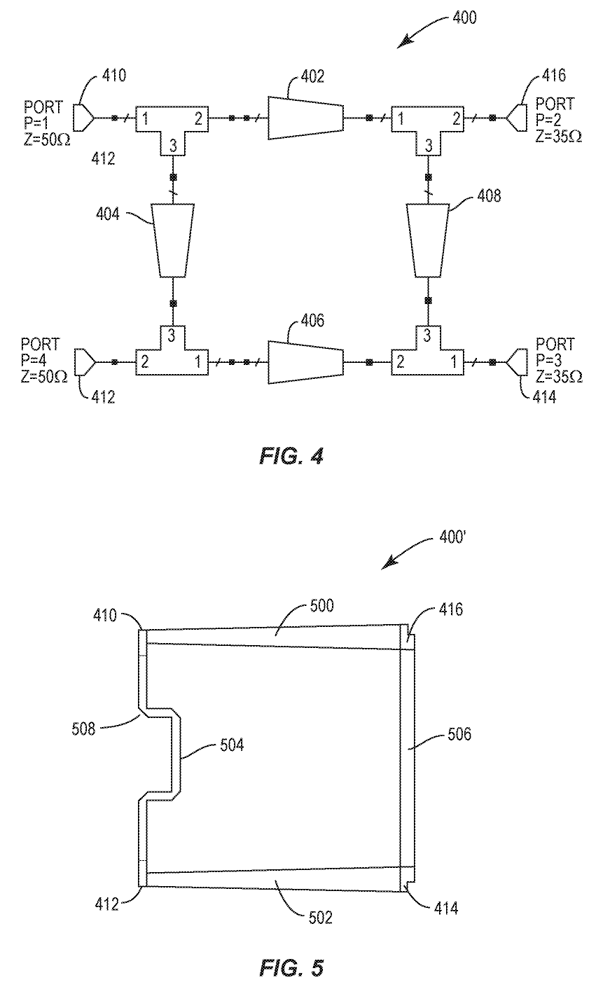

FIG. 4 illustrates a branch line coupler 400, where interior branches 402, 404, 406, and 408 are each tapered. Note that branches 404, 408 are also longer than branches 402, 406 (i.e., effective length is different). Ports 410, 412 have higher impedances (e.g., 50 ohms) while ports 414, 416 have lower impedances (e.g., 35 ohms).

FIG. 5 shows an exemplary implementation of the coupler 400, namely coupler 400’ where only two branches 500, 502 are tapered while branches 504, 506 have a uniform width. That is, FIG. 5 illustrates a microstrip layout of a tapered branchline coupler, with some branches having different line widths and, due to velocity differences, different lengths. Other implementations, such as stripline, in one non-limiting example, would also be possible. Note that branch 504 may include a meander 508 to compensate for velocity differences between wide and narrow branches. Other branches may also have meanders as needed for compactness or velocity differences.

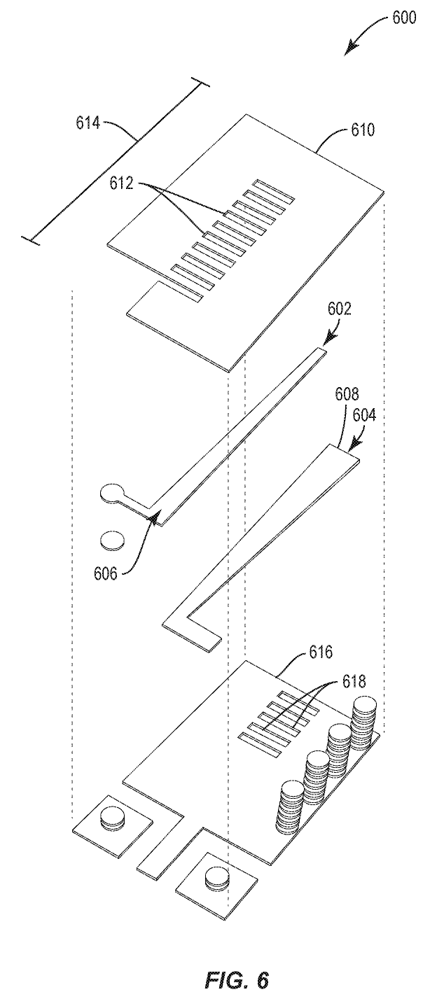

Note that tapering may have an unintended effect in that the coupling to ground may be changed in ways that are undesirable. Accordingly, a defected ground may be used, as better seen in FIG. 6. The coupler 600 has tapered transmission lines 602, 604. Transmission line 602 has wide end 606, and transmission line 604 has wide end 608. A top ground plane 610 may include apertures 612 for approximately half (or less) a length 614 of the transmission line 602. The apertures 612 are positioned above and proximate the wide end 606. Similarly, a bottom ground plane 616 may include apertures 618 below and proximate the wide end 608. Use of the defected ground planes 610, 616 allows the even and odd mode impedances to be kept at reasonable levels for the desired port impedances and coupling.

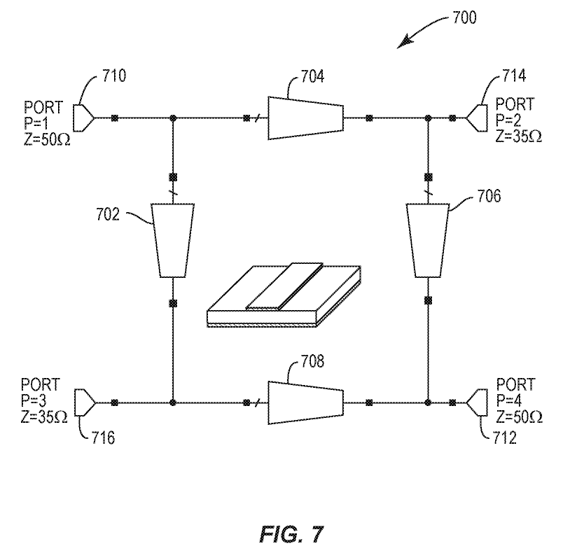

FIG. 7 illustrates a 180-degree hybrid coupler 700 with tapered branch lines 702, 704, 706, 708. Ports 710, 712 have the relatively higher impedances, and ports 714, 716 have the relatively lower impedances. Line 704 is 270 degrees long, while the other lines are 90 degrees long. Line 704 will be approximately three times as long in a physical layout, with slight variation from exactly three times as long due to velocity differences. Lines 702, 706 and 708 will usually be within 30% of the same length due to differences in impedance and the amount of taper, which changes the velocity.

While several couplers have been shown, it should be noted that other couplers may have transmission lines that may be tapered and benefit from the impedance transforming teachings contained herein. For example, March couplers (i.e., nested couplers) having couplers nested in specific legs of the coupler may be modified to have impedance transforming characteristics. Couplers with more than four ports may also benefit from these teachings. Multi-section couplers may also benefit from these teachings.

The impedance transforming couplers according to aspects disclosed herein, while well suited for use in transceivers may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

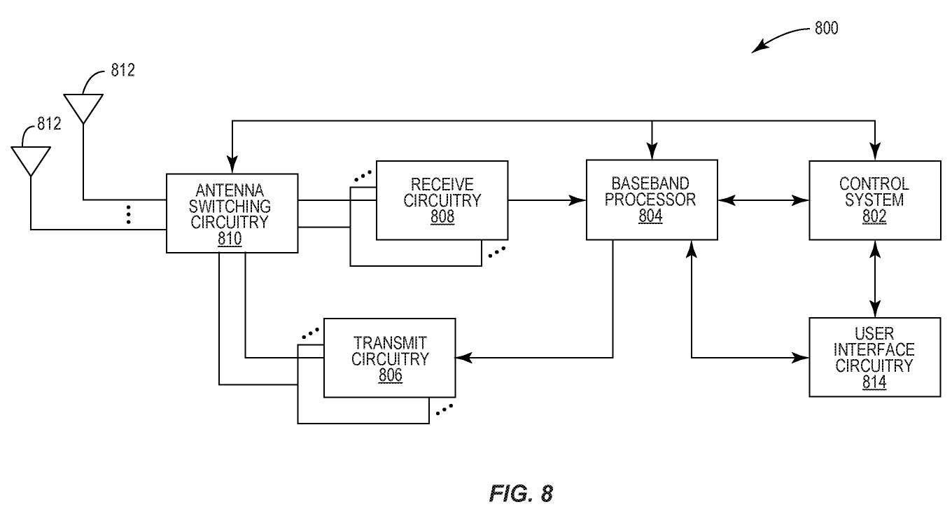

FIG. 8 is a schematic diagram of an exemplary communication device 800 having a transceiver wherein the impedance transforming coupler can be provided. Herein, the communication device 800 can be any type of communication device, such as those listed above as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 800 will generally include a control system 802, a baseband processor 804, transmit circuitry 806, receive circuitry 808, antenna switching circuitry 810, multiple antennas 812, and user interface circuitry 814. In a non-limiting example, the control system 802 can be a field-programmable gate array (FPGA) or an application-specific integrated circuit (ASIC), as an example. In this regard, the control system 802 can include at least a microprocessor(s), an embedded memory circuit(s), and a communication bus interface(s). The receive circuitry 808 receives radio frequency signals via the antennas 812 and through the antenna switching circuitry 810 from one or more base stations. A low noise amplifier and a filter of the receive circuitry 808 cooperate to amplify and remove broadband interference from the received signal for processing. A coupler according to the present disclosure may be present in conjunction with such a low noise amplifier. Down conversion and digitization circuitry (not shown) will then down convert the filtered, received signal to an intermediate or baseband frequency signal, which is then digitized into one or more digital streams using an analog-to-digital converter(s) (ADC).

The baseband processor 804 processes the digitized received signal to extract the information or data bits conveyed in the received signal. This processing typically comprises demodulation, decoding, and error correction operations. The baseband processor 804 is generally implemented in one or more digital signal processors (DSPs) and ASICs.

For transmission, the baseband processor 804 receives digitized data, which may represent voice, data, or control information, from the control system 802, which it encodes for transmission. The encoded data is output to the transmit circuitry 806, where a digital-to-analog converter(s) (DAC) converts the digitally encoded data into an analog signal, and a modulator modulates the analog signal onto a carrier signal that is at a desired transmit frequency or frequencies. A power amplifier possibly having a coupler according to the present disclosure will amplify the modulated carrier signal to a level appropriate for transmission and deliver the modulated carrier signal to the antennas 812 through the antenna switching circuitry 810. The multiple antennas 812 and the replicated transmit and receive circuitries 806, 808 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A coupler comprising:
a first port;
a second port;
a first transmission line extending between the first port and the second port, the first transmission line comprising a first lateral width proximate the first port and a second lateral width proximate the second port, wherein the first lateral width is different than the second lateral width;
a third port;
a fourth port; and
a second transmission line extending between the third port and the fourth port, the second transmission line comprising a third lateral width proximate the third port and a fourth lateral width proximate the fourth port, wherein the third lateral width is different than the fourth lateral width.

2. The coupler of claim 1, wherein the first transmission line comprises a spiral shape between the first port and the second port.

3. The coupler of claim 1, wherein the first transmission line lies in a first plane above the second transmission line in a second plane.

4. The coupler of claim 1, further comprising a third transmission line extending between the first port and the third port.

5. The coupler of claim 4, further comprising a fourth transmission line extending between the second port and the fourth port.

6. The coupler of claim 1, wherein the first lateral width is larger than the second lateral width.

7. The coupler of claim 6, wherein the first lateral width is approximately equal to the third lateral width.

8. The coupler of claim 7, wherein the second lateral width is approximately equal to the fourth lateral width.

9. The coupler of claim 1, wherein the coupler comprises a quadrature coupler.

10. The coupler of claim 1, wherein the coupler comprises a March coupler.

11. The coupler of claim 1, wherein differences in lateral widths cause an impedance transformation along the first transmission line.

12. The coupler of claim 1, wherein the first transmission line comprises a meander between the first port and the second port.

13. The coupler of claim 1, wherein the first transmission line comprises a space filling curve shape between the first port and the second port.

14. The coupler of claim 1, further comprising:
a ground plane; and
a distance defined by a dimension between the first transmission line and the ground plane, wherein the distance varies at different points of the first transmission line, and wherein the variance of the distance causes an impedance transformation along the first transmission line.

15. The coupler of claim 1 integrated into a transceiver.

16. A communication device comprising:
a transceiver comprising:
an amplifier chain comprising:
a single-ended input;
a differential output;
a coupler coupled between the single-ended input and the differential output, the coupler comprising:
a first port;
a second port;
a first transmission line extending between the first port and the second port, the first transmission line comprising a first lateral width proximate the first port and a second lateral width proximate the second port, wherein the first lateral width is different than the second lateral width;
a third port;
a fourth port; and
a second transmission line extending between the third port and the fourth port, the second transmission line comprising a third lateral width proximate the third port and a fourth lateral width proximate the fourth port, wherein the third lateral width is different than the fourth lateral width.

17. A method of forming a coupler to provide impedance transformation between a single-ended input and a differential output, the method comprising:
forming a first port and a second port with a first transmission line extending between the first port and the second port, the first transmission line comprising a first lateral width proximate the first port and a second lateral width proximate the second port, wherein the first lateral width is different than the second lateral width; and
forming a third port and a fourth port with a second transmission line extending between the third port and the fourth port, the second transmission line comprising a third lateral width proximate the third port and a fourth lateral width proximate the fourth port, wherein the third lateral width is different than the fourth lateral width.

18. The method of claim 17, further comprising varying a distance between the first transmission line and a ground plane.

19. The method of claim 17, further comprising forming the first transmission line with a meander or spiral shape.

20. The method of claim 17, further comprising forming a March coupler in the coupler.
